(19) United States
(12) Patent Application Publication
(10) Pub. No.: US 2017/0073805 A1
(43) Pub. Date: Mar. 16, 2017

(54) FABRICATION METHODOLOGY FOR THIN FILM LITHIUM ION DEVICES

(71) Applicant: E-Chromic Technologies, Inc., Boulder, CO (US)

(72) Inventors: Bruce D. Gittleman, Centennial, CO (US); David Alie, Golden, CO (US)

(21) Appl. No.: 15/142,936

(22) Filed: Apr. 29, 2016

Related U.S. Application Data
(60) Provisional application No. 62/155,093, filed on Apr. 30, 2015.

(51) Int. Cl. C23C 14/34; G02F 1/15; C23C 14/08; H01M 10/0525; H01M 4/04

(52) U.S. Cl. CPC C23C 14/3485; H01M 10/0525; H01M 4/0426; C23C 14/086; G02F 1/1523

(57) ABSTRACT

A method of making multilayer thin film Li-ion devices that can involve direct current (DC) sputtering of a metal current collector film or pulsed DC sputtering (PDC) of a transparent conducting oxide (TCO) onto a substrate, depositing a very thin metal diffusion barrier using high power impulse magnetron sputtering (HPIMS), depositing one or more ion storage layers or a cathode layer and an electrolyte layer by PDC sputtering or reactive PDC sputtering of a non-insulating target, and depositing a TCO via PDC sputtering or depositing an anode layer by PDC sputtering and a metal current collector by DC sputtering, the combination of these layers depending on the particular device being fabricated.

### CROSS-REFERENCE TO RELATED APPLICATIONS

This application claims priority to and the benefit of U.S. Provisional Patent Application Ser. No. 62/155,093, entitled “Fabrication Methodology for Thin Film Lithium Ion Devices,” filed Apr. 30, 2015, the disclosure of which is hereby incorporated by reference in its entirety.

### BACKGROUND

Thin film lithium ion devices, such as solid state batteries (e.g., thin film batteries, “TFBs”), reflective electrochromics (RECs) and absorptive electrochromics have applications in many electronic devices. For example, RECs can be used in energy saving window and privacy glass applications, while TFB applications include lighter and thinner mobile electronics, implantable medical devices, and wireless sensors.

### SUMMARY

Methods of making multilayer thin film Li-ion devices described herein can involve direct current (DC) sputtering of a metal current collector film or pulsed DC sputtering (PDC) of a transparent conducting oxide (TCO) onto a substrate, depositing a very thin metal diffusion barrier using high power impulse magnetron sputtering (HPIMS or HIPIMS), depositing one or more ion storage layers by PDC sputtering of a non-insulating target, an electrolyte layer by PDC sputtering, reactive PDC sputtering, or a combination of DC, reactive DC, PDC, and/or reactive PDC with a small oscillating sputter component either at an RF frequency or non-RF frequency (referred to as a Ripple from this point forward) of a non-insulating target, and/or depositing a TCO via PDC sputtering, and/or depositing an anode by PDC sputtering followed by deposition of a metal current collector by DC sputtering, the combination of these layers depending on the particular device being fabricated. The electrolyte can also be deposited from an insulating target by employing an alternating current/voltage sputter source that does not operate in the RF frequency range or ionized physical vapor deposition (iPVD) sputtering.

In some embodiments, a method of making a reflective electrochromic device includes depositing, via pulsed direct current sputtering, a first transparent conducting oxide material on a substrate. A diffusion barrier is then deposited on the first transparent conducting oxide material positing, via high power impulse magnetron sputtering. An electrolyte layer is deposited. An ion storage layer is deposited via pulsed direct current sputtering, and a second transparent conducting oxide material is deposited via pulsed direct current sputtering, a second transparent conducting oxide material.

In some embodiments, a method of making an absorptive electrochromic device includes depositing a first transparent conducting oxide material on a substrate via pulsed direct current sputtering. A first ion storage layer is then deposited via pulsed direct current sputtering, followed by an electrolyte layer. A second ion storage layer is deposited on the electrolyte layer via pulsed direct current sputtering, and then a second transparent conducting oxide material is deposited via pulsed direct current sputtering.

In some embodiments, method of making a lithium ion battery includes depositing a first layer via direct current sputtering. A cathode layer is deposited on the first layer via at least one of pulsed direct current sputtering and reactive pulsed direct current sputtering. An electrolyte layer is deposited on the cathode layer via pulsed direct current sputtering, a metallic anode is deposited on the electrolyte layer via pulsed direct current sputtering, and then a second layer is deposited on the metallic anode via direct current sputtering.

### BRIEF DESCRIPTION OF THE DRAWINGS

FIG. 1 is a flow diagram depicting a process methodology for depositing one or more films of a desired material, according to an embodiment.

FIG. 2 is a flow diagram depicting a process methodology for depositing one or more films of a desired material, including selection of a deposition technique, according to an embodiment.

FIGS. 3A-3C are schematic illustrations of cross-sectional views of thin film devices, according to various embodiments.

FIG. 4 is a schematic depiction of a radio frequency (“RF”) plasma deposition system, according to an embodiment.

FIG. 5 is a schematic depiction of a direct current (“DC”) plasma deposition system, according to an embodiment.

FIG. 6 is a schematic depiction of a pulsed direct current (“PDC”) plasma deposition system, according to an embodiment.

FIG. 7 is a schematic depiction of an ionized physical vapor deposition (“iPVD”) plasma system, according to an embodiment.

FIG. 8 is a schematic depiction of an iPVD plasma system, according to an embodiment.

FIG. 9 is a schematic depiction of an iPVD plasma system, according to an embodiment.

FIG. 10 is a schematic depiction of a DC RF or medium frequency (“MF”) Ripple plasma deposition system, according to an embodiment.

FIG. 11 is a schematic depiction of another DC RF or MF Ripple plasma deposition system, according to an embodiment.

FIG. 12 is a schematic depiction of a MF plasma deposition system, according to an embodiment.

FIG. 13 is a schematic depiction of a MF RF Ripple plasma deposition system, according to an embodiment.

FIGS. 14A-14F show a sequence of simulated effects of ion impact on an existing film or a substrate.

FIGS. 15A and 15B show schematic cross-sectional views illustrating substrate bias-induced ion diffusion between deposited layers.

FIG. 16 is a photograph of an initially transparent oxide coated with RF sputtered lithium phosphorus oxynitride (“LiPON”) that shows the effects of substrate bias-induced ion diffusion between deposited layers of a multilayered film structure.

FIGS. 17A and 17B are two photographs, each showing an oscilloscope trace of voltage over time for a PDC waveform.

FIG. 18 shows a deposition technique selection methodology according to an embodiment.

FIG. 19 shows an REC fabrication process methodology according to an embodiment.

FIG. 20 shows an AEC fabrication process methodology according to an embodiment.

FIG. 21 shows a TFB fabrication process methodology according to an embodiment.

### DETAILED DESCRIPTION

Embodiments described herein relate generally to methods of making a multilayer thin film lithium ion device. Some such methods include direct current (DC) sputtering of a metal current collector film onto a substrate, depositing a very thin metal diffusion barrier using high power impulse magnetron sputtering (HPIMS or HIPIMS), depositing an ion storage or cathode layer and an electrolyte layer by pulsed direct current (PDC) sputtering or reactive PDC sputtering of a non-insulating target, and depositing a transparent conducting oxide (TCO) via PDC sputtering.

The implementation of thin film lithium ion (Li-ion) devices into consumer and industrial products has been limited by an inability to manufacture them with high yield at low cost. Furthermore, manufacturing processes for thin film Li-ion devices—which typically include multiple layers of materials (i.e., “thin film” multilayer devices)—often do not take into account the fact that: (1) Li-containing materials can be highly reactive with other materials, particularly when the composition of as-deposited Li-containing layers differs from a desired stoichiometry, and (2) Li forms a highly mobile ion that can readily diffuse into other layers in a multilayer stack of films. The electrical, optical and/or mechanical properties of Li-containing layers, once deposited, are a function of, and can be highly sensitive to, their composition (e.g., their “stoichiometry”) as well as any defects that may be present, such as voids, cracks, inclusions, discontinuities, thickness and compositional non-uniformities, etc. This sensitivity can have a negative impact on the performance and lifetime of devices that contain such layers. A fabrication sequence that results in contiguous Li-containing layers having low defect densities and proper composition prevents Li ion interdiffusion and reaction between layers during fabrication and is highly desirable. Also, when diffusion barriers are used to prevent Li ion diffusion into other device layers such as a TCO, current collector or the substrate, continuity of the diffusion barrier is critical in preventing unwanted migration of Li. Devices fabricated with these properties could lead to a more widespread adoption and/or implementation of thin film Li-ion devices into consumer and industrial products.

Manufacturing processes for Li-ion devices often employ the sputtering of solid targets (i.e., “sputtering targets”) to produce the device layers that store Li ions, the electrolyte layer through which Li ions travel during charging and discharging, and/or the device electrodes and diffusion barriers. There are several types of sputtering, including DC, radio frequency (RF), PDC, frequencies below RF, such as medium or mid frequency (MF) and frequencies below MF, such as alternating current (AC), ionized physical vapor deposition (“iPVD”) and HPIMS. For example, RF sputtering, a sputtering process in which a voltage applied to the sputtering target alternates in polarity between positive and negative at a predetermined frequency, typically 13.56 MHz, but herein defined as any frequency between 1 MHz and 300 MHz, is often used to deposit the ion storage and electrolyte layers of thin film Li-ion devices. An alternating voltage (e.g., via RF sputtering) can be used when the sputtering target is an insulator (i.e., an electrically insulating target), for example as is the case with some electrolyte target materials (e.g., lithium phosphate (Li₃PO₄)). In some embodiments, the lithium phosphate target can be doped with metals, such as aluminum, silver or nickel to be more conductive. The doping of these metals in a lithium phosphate target can be up to 10 percent by weight. In such processes, the insulating target may be sputtered in the presence of an inert gas (e.g., argon gas), or may be sputtered in the presence of a non-inert gas (e.g. nitrogen or oxygen) or gas mixture (e.g., an argon/nitrogen gas mixture), the latter two techniques referred to herein as “reactive deposition.” During reactive deposition, an element in the sputtering gas is incorporated into the material that is being sputtered from the target (i.e., incorporated into the film as it is being deposited). The sputtering materials and conditions used can have a significant impact on the stoichiometry of the resulting film. Reactive RF sputtering of Li₃PO₄ in a nitrogen gas or an argon/nitrogen gas environment can result in a substantially stoichiometric lithium phosphorus oxynitride (“LiPON”) film. Physical evaporation (PE) or DC sputtering are often used to deposit the metal electrodes. Typical process methodologies for electrochromic devices and thin film batteries are presented in Tables 1 and 2 below, respectively. In some instances, PDC sputtering can be used for the anodic ion storage and cathode layers if the sputter target is made from a semiconducting material. For example, an anodic ion storage layer can be deposited via PDC sputtering or RF sputtering of a lithium nickel oxide (LiNiO₂) target. In some embodiments, the LiNiO₂ target can have a varying oxygen concentration such that LiNiO_{2±x} where x is approximately 0.3. In some embodiments, the resulting lithium nickel oxide layer can have a varying oxygen concentration such that LiNiO_{2±x} where x is approximately 0.3. In some embodiments, the sputtering is performed under reactive environment to control the oxygen concentration in the resulting lithium nickel oxide layer. Likewise, an electrolyte layer can be posited via PDC sputtering or RF sputtering of a lithium phosphate target in a reactive environment or inert environment. A TCO layer can be deposited via PDC sputtering of an indium tin oxide (ITO) target on the substrate. In some embodiments, a thin layer of tantalum (Ta) can be deposited and the tantalum layer can act as an adhesive layer. For AEC devices, an anodic ion storage layer comprising lithium vanadium oxide (LiV₂O₅) can be deposited via PDC sputtering or RF sputtering of a LiV₂O₅ target. As for the cathodic ion storage layer, a tungsten oxide layer can be deposited via DC sputtering of a tungsten target in oxygen. In some embodiments, PDC sputtering is preferred for producing a pure Li anode, as indicated by “*” next to PDC in Table 2. In some embodiments, Li can also be deposited using PE or AC sputtering.

For thin film battery (TFB) devices, the current collectors can be at least one of gold, nickel and metal oxynitrides that do not react with any of the lithium comprising cathode materials. Some example of these cathode materials included in the cathode layer can be at least one of lithium cobalt oxide, lithium cobalt dioxide, lithium nickel oxide, lithium iron phosphate, lithium manganese oxide, and lithium nickel cobalt oxide. The electrolyte layer in the TFB devices can be the LiPON material as described above. Li metal is used in the TFB as the anode metal.

TABLE 1

| | | | Target | |
|---|---|---|---|---|
| Electrochromic | Deposited | | Electrical | Sputter |
| Device Layer | Material | Target | Properties | Method |
| TCO | ITO | ITO | Semiconductor | PDC |
| Anodic Ion | LiNiO₂ | LiNiO₂ | Semiconductor | RF |
| Storage Layer | | | | |
| type 1 | | | | |
| Anodic Ion | LiV₂O₅ | Li₂VO₅ | Insulator | RF |
| Storage Layer | (AEC only) | | | |
| type 2 | | | | |
| Electrolyte | LiPON | Li₃PO₄ | Insulator | RF |
| Cathodic Ion | WOₓ | W | Conductor | DC |
| Storage Layer | | | | |
| Metal | Ta (REC only) | Ta | Conductor | DC |

TABLE 2

| | | | Target | |
|---|---|---|---|---|
| Thin Film Battery | Deposited | | Electrical | Sputter |
| Layer | Material | Target | Properties | Method |
| Current collectors | Au, Ni | Au, Ni | Conductor | PDC |
| Anode | Li | Li | Conductor | PDC* |
| Electrolyte | LiPON | Li₃PO₄ | Insulator | RF |
| Cathode | LiCoO₂ | LiCoO₂ | Semiconductor | RF |

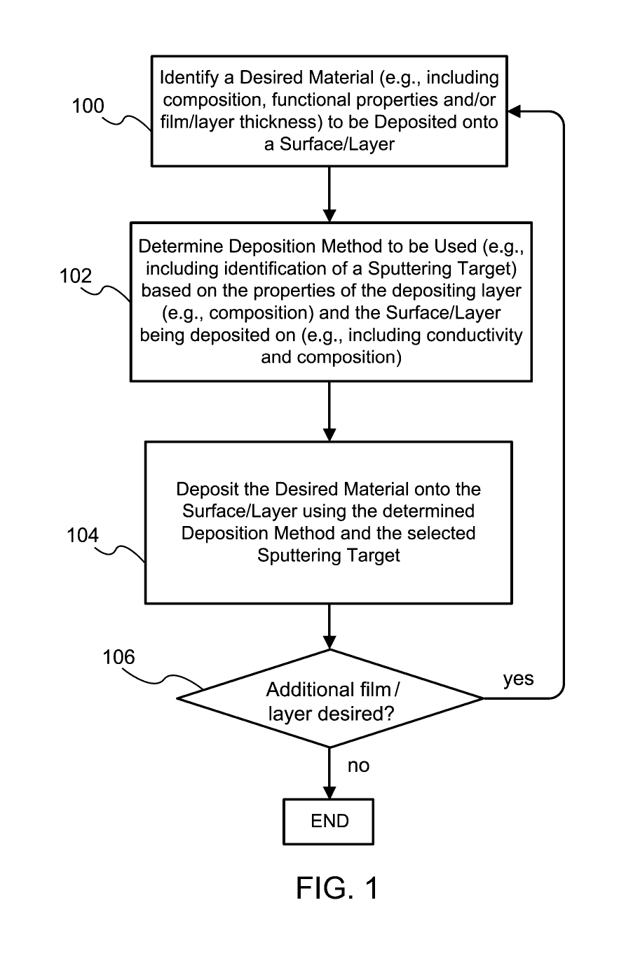

FIG. 1 is a flow diagram depicting a process methodology for depositing one or more films of a desired material, according to an embodiment. Methods described herein, as exemplified by the process shown in FIG. 1, can be used for the fabrication of one or more thin film devices, for example Li-ion devices such as electrochromic devices (e.g., reflective electrochromic (REC) devices or absorptive electrochromic (AEC) devices), thin film batteries (TFBs), and/or the like. Such devices can comprise a plurality of functional thin film layers, each configured to have a desired value of one or more of the following properties: electrical conductivity, ionic (e.g., lithium) conductivity, electrical insulation (does not conduct electrons), optical transparency (e.g., transmittance in the visible light spectrum), and chemical inertness (e.g., in the presence of lithium, aluminum, copper, etc.). For example, an electrochromic device can comprise several layers, including (but not limited to) one or more of the following (listed here in no particular order): a lithium ion storage layer (e.g., cathodic and/or anodic), an ion conductor layer, an electrically conductive transparent layer, and an electrolyte layer (e.g., comprising LiPON), and/or a thin metal barrier layer, as described in greater detail below.

As shown in FIG. 1, a desired material is first identified, at 100, for deposition onto a surface (i.e., in the form of a “thin film”), for example as part of a device fabrication process. Identification of the desired to-be-deposited material can include an identification of its desired properties (e.g., elemental composition, stoichiometry, material properties, functional properties, etc.) and/or one or more physical parameters, such as a thickness to which it will be deposited. As used herein, the phrase “thin film” refers to a film of a material having a thickness (e.g., an average thickness) of from a single atomic layer (i.e., sub-nanometer) up to tens of micrometers in thickness. The type of deposition method (e.g., including identification of an appropriate sputtering target) to be used is then determined, at 102, based on the properties of the depositing layer (e.g., its composition) and the surface/layer being deposited on (e.g., including its conductivity and composition). For example, in some instances a first film or “layer” may be deposited onto a bare (uncoated) substrate. In other instances, a film is deposited onto a pre-existing film (which may be continuous or discontinuous) that was either native to the substrate as obtained, or was previously deposited (e.g., within the same deposition or using a different deposition tool), as part of a multi-layer (and, hence, multiple step) manufacturing process. For example, if an ion storage layer (e.g., tungsten oxide (WOₓ) is being deposited onto a previously deposited transparent conductor layer (e.g., TCO), there is no concern for lithium diffusion into the TCO, as both the surface receiving the deposition, as well as the depositing material, are lithium-free. The voltage that develops during the deposition of the ion storage layer is likely not a concern and any of the deposition techniques mentioned above can be used to deposit the WOₓ onto to the TCO without interdiffusion occurring between them. By contrast, if an electrolyte layer (e.g., LiPON) is to be deposited onto a surface onto which an ion storage or TCO layer has already been deposited, there is a possibility for interdiffusion of Li from the electrolyte source material into the ion storage or TCO layer during the deposition of the electrolyte or interdiffusion from the ion storage layer into the electrolyte. In such instances, only a deposition method which induces only a low bias on the substrate can be selected for the electrolyte deposition, to mitigate such interdiffusion.

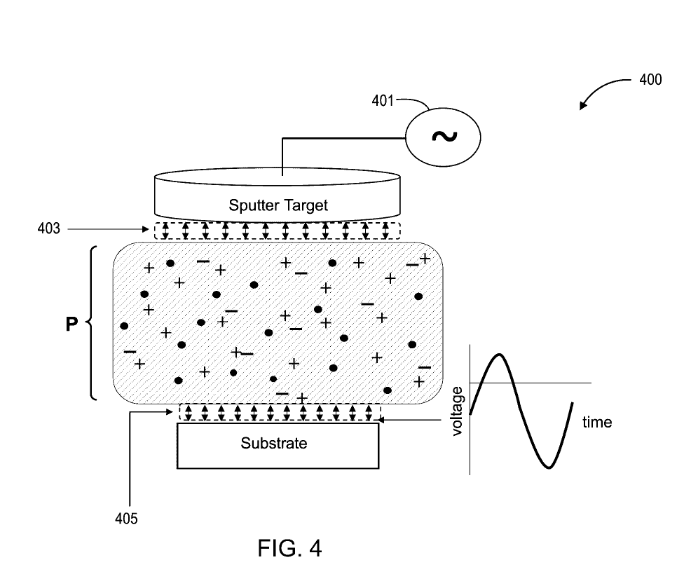

The determination of the “type of deposition” can refer to the technique (e.g., DC sputtering, PDC sputtering, HPIMS, iPVD, and RF sputtering, each described in detail below with reference to FIGS. 4-13) as well as to the conditions to be used for the deposition of the desired material using the selected technique. Such conditions can include (but are not limited to): applied sputtering power, frequency, base vacuum pressure prior to sputtering, sputtering gas(es), partial pressure of the sputtering gas(es) during deposition, flow rates of the sputtering gas(es), applied temperature (e.g., heating or cooling) to the substrate and/or process chamber, sputter duration, substrate ion assist voltage, etc. In some embodiments, selection of a deposition technique takes into account the nature of the target source material to be used (e.g., conductive or insulating nature of the sputtering target). In some embodiments, a DC or PDC sputtering process is selected when the sputtering target is metallic (single metal or metal alloy) In some embodiments, a PDC sputtering process is selected when the sputtering target has a DC resistance, as measured with a standard multimeter with the probe tips positioned about ½″ apart, of <about 10 MΩ, for example certain oxides and semiconductors. In some embodiments, a DC RF Ripple or DC MF Ripple sputtering or iPVD process is selected when the sputtering target has a DC resistance, as measured with a standard multimeter with the probe tips positioned about ½″ apart, of >about 10 MΩ but <about 20 MΩ. In some embodiments, a MF sputtering or iPVD process is selected when the sputtering target is substantially electrically insulating (e.g., having a resistance, when probed with a standard multimeter on its surface and found to be too high to be measured). At 104, the desired material is deposited onto the surface/layer according to the determined deposition method, and using the selected sputtering target. In some embodiments, the sputtering target is “pre-cleaned” (e.g., “pre-sputtered” in the presence of a shutter blocking line-of-sight with the substrate, or done prior to introducing the substrate to the deposition chamber), such that any native oxides, nitrides, and/or contamination is removed from the surface of the sputtering target prior to the sputtering of the device layer(s). The sputter deposition is performed in a vacuum chamber (e.g., a high-vacuum deposition chamber configured to be pumped down to a pressure as low as 5×10⁻⁶ Torr, or to a pressure as low as 3×10⁻⁷ Torr, or to a pressure as low as 1×10⁻⁸ Torr, using a turbopump, a cryopump, a cold trap, a physical displacement pump, or a combination thereof, and/or the like). A sputtering target resides in a sputtering “gun” within the chamber, and the substrate (also referred to herein as a “sample,” and which may or may not already include a film) is loaded either directly into the chamber, or into a “load lock” chamber coupled to the main deposition chamber, or into a load lock coupled to a substrate transfer chamber which is itself coupled to one or more deposition chambers. In deposition tools with a load lock or substrate transfer chamber, the tool is equipped with a transfer mechanism configured to transfer the sample into the main deposition chamber once a predetermined vacuum level is reached therein and in the load lock and sample transfer chamber. The deposition chamber is pumped down to a “base” pressure that is sufficiently low so as to eliminate significant sources of contamination (e.g., moisture, gases, particulate, etc.). One or more sputtering gases (inert and/or reactive) are introduced into the chamber, e.g., by way of a mass flow controller, to a specified increased pressure. Each gas introduced into the chamber contributes a “partial pressure” to the overall chamber pressure. A pre-sputtering cleaning step, whereby power is applied to the sputtering gun, causing sputtering of the sputtering target surface and, correspondingly, ejection of a surface layer thereof, can be performed. Sputtering of the chosen material, by the chosen sputtering method, is then performed in the presence of the sample, which may be positioned directly below, above or adjacent to, or otherwise in close proximity to, the active sputtering target, depending on whether sputter-down, sputter-up or sputter-sideways is employed. During sputtering, a voltage applied to the sputtering target generates a plasma, from which energetic ions bombard the surface of the sputtering target, causing ejection of atoms therefrom. At least some of the ejected atoms are directed towards, and land on, the substrate and organize into a thin film. In some embodiments, a thickness of the sputtered layer is monitored by one or more sensors (e.g., a quartz crystal deposition rate monitor), or by sputter time, allowing for the termination of the sputtering event once the desired thickness has been obtained. In some embodiments, a temperature at the substrate during sputter deposition does not exceed 100° C. The temperature of a sputtering process can be characterized and/or monitored by one or more thermocouple probes positioned within the deposition chamber (e.g., embedded in the substrate holder). The temperature of the substrate may be actively controlled or not be controlled at all. At 106, it is determined whether an additional layer is required. If so, the process iterates, beginning again at 100. If not, the process terminates.

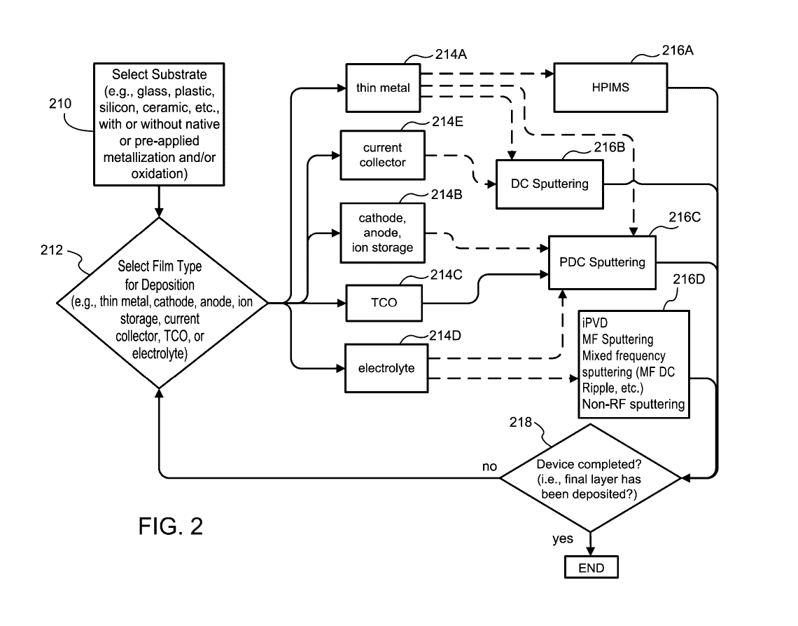

FIG. 2 is a flow diagram depicting a process methodology for depositing one or more films of a desired material, including selection of a deposition technique, according to an embodiment. The deposition techniques shown in FIG. 2, while representative, are not a fully inclusive list, and other possible deposition methodologies will be discussed subsequently. At 210, a substrate is selected (e.g., glass, plastic, silicon, ceramic, etc., with or without native or pre-applied metallization and/or oxidation). The desired to-be-deposited film type is then determined, at 212, from the following: thin metal, cathode, anode, ion storage, current collector, TCO, or electrolyte. If thin metal is selected (214A), the deposition method can be HPIMS (216A), DC sputtering (216B), or PDC sputtering (216C). If cathode, anode, or ion storage layer, is selected (214B), the deposition method can be PDC sputtering (216C). If current collector (214E) is selected then the deposition method can DC sputtering (216B). If TCO is selected (214C), the deposition method is PDC sputtering (216C). If electrolyte is selected (214D), the deposition method can be PDC sputtering (216C) or iPVD (216D). Upon completion of the selected deposition process for the selected layer, it is determined (at 218) whether an additional layer is required. If so, the process iterates by returning to 212. If not, the process terminates.

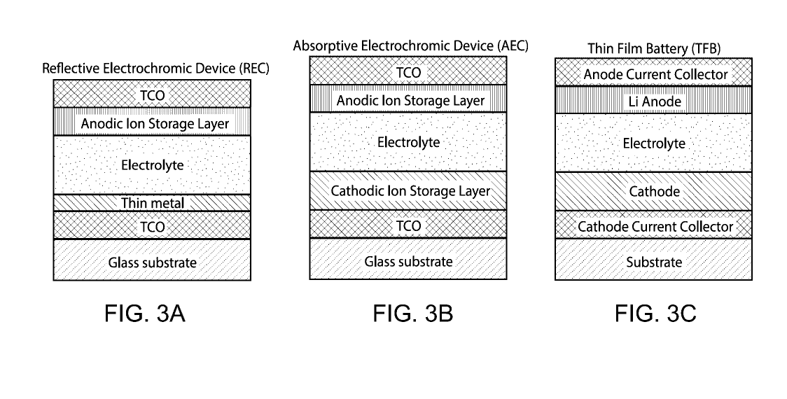

FIGS. 3A-3C are schematic illustrations of cross-sectional views of thin film devices, according to various embodiments. In some embodiments, for example as shown in FIG. 3A (depicting an example multilayered REC), an electrochromic device includes a stack of film layers that is switchable between a reflective state and a transparent state through the application of electrical potential across the stack. The stack can comprise several layers, including (but not limited to) one or more of the following (listed here in no particular order): a ion storage layer that contains lithium (e.g., anodic), two electrically conductive transparent layers (e.g., TCO), and/or an electrolyte layer (e.g., comprising LiPON) which conducts lithium ions but not electrons, and/or a thin metal barrier layer. For example, an electrochromic device according to one embodiment comprises, sequentially: a first electrically conductive transparent layer (e.g. a TCO), a lithium ion storage layer comprising lithium ions, an ion conductor layer (e.g., an electrolyte), and a second electrically conductive transparent layer (e.g., a TCO). An electrically conductive transparent layer can include a transparent conducting oxide (such as indium tin oxide (“ITO”), fluorine doped tin oxide, aluminum doped zinc oxide, etc.). In some embodiments, the electrically conductive transparent layer can include a lithium-oxide transparent conducting oxide material. An ion conductor layer can include one or more of: LiPON, lithium aluminum fluoride, a member of the Lisicon family of lithium ion conductors or other lithium ion conducting thin films, such as lithium lanthanum titanate, lithium containing sulfide glasses such as Li₂S—SiS₂—Li₄SiO₄, lithium conducting garnets such as Li₅La₃M₂O₁₂ (where M=Ta, Nb) and/or the like. In some embodiments, LiPON is LiₓPO_{y}N_{z}, where x=2y+3z−5 or Li₃PO₄₋ₓNₓ. One or more of the layers can comprise one or more sub-layers having different compositional and/or physical properties. Each layer can be continuous (e.g., sufficiently thick so as to form a single, uninterrupted layer and/or free from pinholes) or discontinuous (e.g., patterned and/or comprising a plurality of islands). One or more of the layers (e.g., the ion conductor layer) can comprise a polymeric material or other lithium ion conductor system, for example adducts of polymers, such as polyethylene oxide, polypropylene oxide and polyethylene imine with lithium salts. An electrolyte layer can comprise a solid polymer electrolyte and/or a gel electrolyte.

When the stack of an electrochromic device is switched from the transparent state to the reflective state, lithium ions move from the Li-ion storage layer into and through the ion conductor layer and a Li-reflective feature forms (e.g., is electroplated) on the electrolyte surface opposite that of the ion storage layer and adjacent to the thin metal diffusion barrier layer or TCO if a metal diffusion barrier is not required. When the stack is switched from the reflective state to the transparent state, the reflective feature is removed and Li-ions move through the ion conductor layer back into the lithium ion storage layer. When the stack is in the clear, transmissive, or transparent state, the stack can have a transmittance of visible light (e.g., light having a wavelength of about 400 nm to about 700 nm) of at least about 50 percent, and up to about 85 percent. When the stack is in the reflective state (e.g., the Li-reflective feature is present), the stack can have a transmittance of visible light (e.g., light having a wavelength of about 400 nm to about 700 nm) of not more than about 30 percent to less than about 5 percent (at less than 5 percent transmittance, the unaided eye cannot perceive an object or person behind the device).

As shown in FIG. 3B, an absorptive electrochromic device (AEC) of the disclosure can include a plurality of layers, disposed on a glass substrate and including: a first TCO layer, a cathodic ion storage layer, an electrolyte layer, an anodic ion storage layer, and a second TCO layer. As shown in FIG. 3C, a thin film battery (TFB) of the disclosure can include a plurality of layers, disposed on a ceramic or metallic substrate and including: a cathode current collector, a cathode, an electrolyte, a lithium-containing layer, an anode and an anode current collector.

FIG. 4 is a schematic depiction of a radio frequency (“RF”) plasma deposition system 400, according to an embodiment. Plasmas are made up of neutral gas atoms (“”), positive charges (positive ions, “+”) and negative charges (electrons and negative ions, “−”). An RF Power Supply 401 supplies an oscillating voltage to the sputter target, and arrows (pointing up and down) adjacent to the lower face of the sputtering target denote the oscillating nature of the electric field in the plasma sheath. The RF plasma is a capacitive medium density plasma that spreads over most of the deposition chamber, and extends from the sputter target to the substrate. Arrows (pointing up and down) adjacent to the substrate denote the plasma sheath electric field that accelerates ions to the substrate surface, causing ejection (sputtering) of substrate atoms. Electrons are accelerated to the substrate as well. The corresponding accelerating voltage is a function of the plasma potential and the induced substrate voltage.

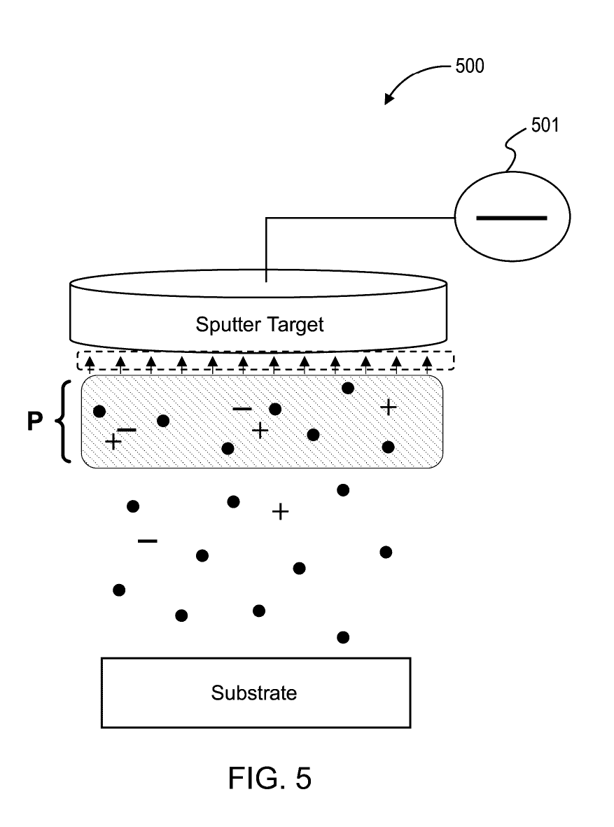

FIG. 5 is a schematic depiction of a direct current (“DC”) plasma deposition system 500, according to an embodiment. A DC power supply 501 supplies a constant voltage to the sputter target, thereby generating a DC plasma “P” that is restricted in physical extent, as compared with RF sputtering. In other words, the DC plasma is substantially confined to the vicinity of the sputter target surface, as shown in FIG. 5. DC sputtering produces the lowest ratio of ions and electrons to neutral atoms, as compared with other sputter-generated plasmas. There is no, or negligible, plasma at the substrate surface, and no (induced bias related) acceleration of ions to the substrate.

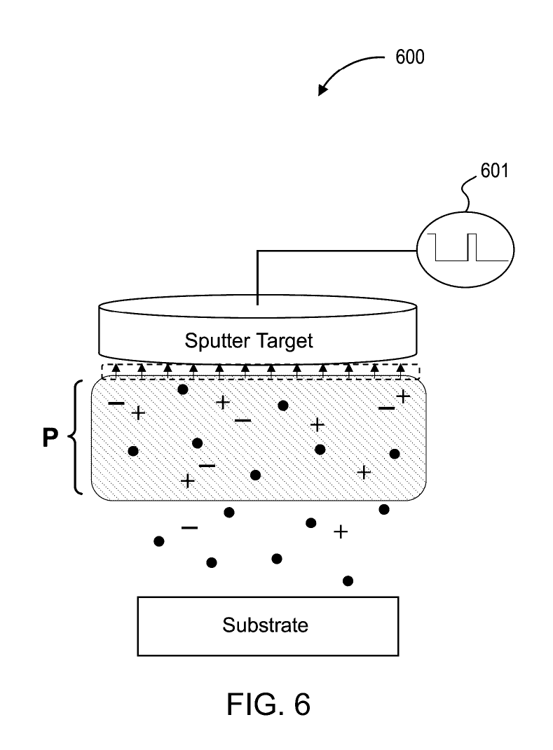

FIG. 6 is a schematic depiction of a pulsed direct current (“PDC”) plasma deposition system 600, with RF oscillation and voltage spike control, according to an embodiment, such that the pulse closely approximates an ideal square wave. A PDC power supply 601 supplies a switching DC voltage (switches in polarity) to the sputter target. PDC plasmas are typically confined to the vicinity of the sputter target surface, but can extend farther (i.e., in the direction of the substrate) than a DC plasma can, and are more dense (i.e., a higher concentration of ions and electrons). There is no, or negligible, plasma at the substrate surface, and no (induced bias related) acceleration of ions to the substrate during the sputtering cycle. Ions in the vicinity of the target when the voltage is reversed (e.g., made positive) can be accelerated towards the substrate with the full reverse potential of the target, which is why it is important to be able to control the magnitude of the reverse pulse.

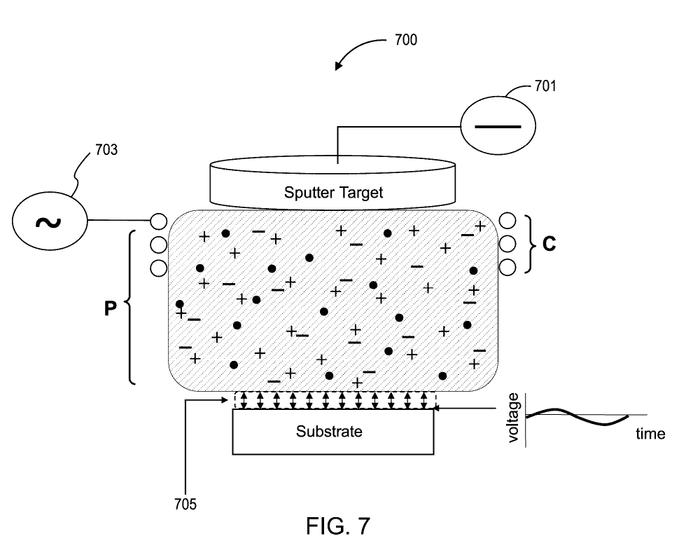

FIG. 7 is a schematic depiction of an ionized physical vapor deposition (“iPVD”) plasma system 700, according to an embodiment. A constant-voltage DC power supply 701 applies a constant voltage (i.e., constant voltage level and polarity) to the sputter target, while a high power RF supply 703 supplies RF power to an RF coil C surrounding the plasma sheath region adjacent to the sputter target. iPVD plasmas spread over most of the deposition chamber, extending to the substrate, are inductive, and have a very high plasma density (i.e., of energetic species such as ions and electrons). There is a very small oscillating voltage imparted to the substrate, and a plasma sheath is formed at the substrate surface. In some embodiments, the iPVD method can be performed in an inert environment containing argon gas. In some embodiments, the iPVD method can be performed in a reactive environment (i.e., reactive iPVD) using at least one of oxygen, nitrogen, and argon gases (e.g. argon/nitrogen, argon/oxygen, argon/oxygen/nitrogen, or oxygen/nitrogen).

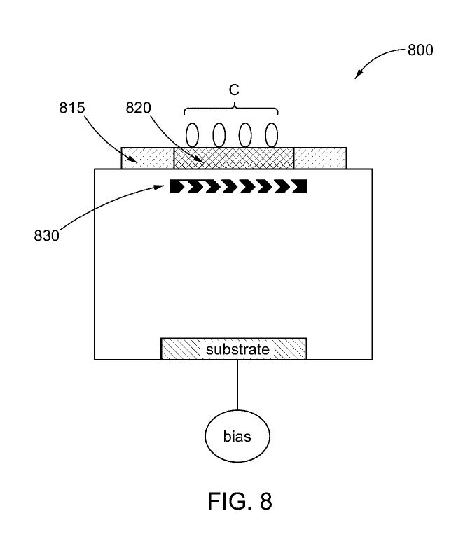

FIG. 8 is a schematic depiction of another ionized physical vapor deposition (“iPVD”) plasma system 800, according to an embodiment showing an external coil configuration. As shown, an RF coil “C” is disposed atop a dielectric window 820 that is surrounded by a sputtering target material 815. The ceramic window provides a vacuum seal as well as allowing energy from the RF coil to penetrate into the chamber. Included within the chamber is a Faraday shield/deposition baffle 830, for example to prevent significant deposition of the target material on the dielectric window, which can attenuate the RF energy in the plasma volume, and to reduce the magnitude of the normal electric field from the RF coil. In the configuration of FIG. 8, a substrate bias can also be applied.

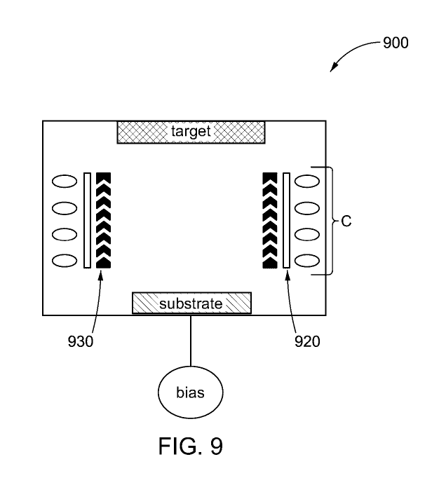

FIG. 9 is a schematic depiction of another ionized physical vapor deposition (“iPVD”) plasma system 900, according to an embodiment showing an internal coil configuration. As shown, an RF coil “C” surrounds a cylindrical dielectric window 920 that, itself, surrounds a Faraday shield/deposition baffle 930. As shown in FIG. 8, the ceramic both provides a vacuum seal and allows for transmission of RF energy into the chamber. The target is DC magnetron sputtered. In the configuration of FIG. 9, a substrate bias can also be applied.

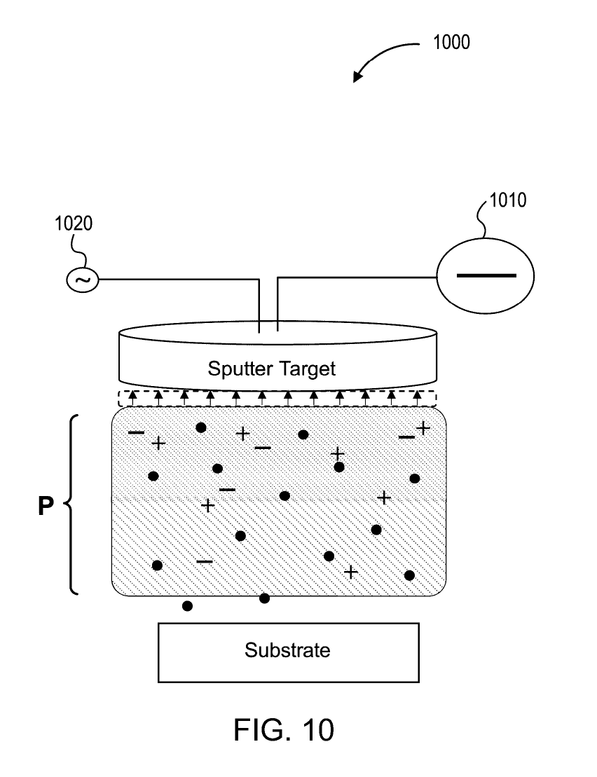

FIG. 10 is a schematic depiction of a DC RF Ripple plasma deposition system 1000, according to an embodiment. A DC power supply 1010 and a low power RF or MF supply 1020 supply power to the sputter target. The DC RF Ripple plasma has a similar physical extent to that of the PDC system, but can extend further in the direction of the substrate, and weakens in intensity with distance from the target, such that there is very diffuse or no plasma in the region adjacent to the substrate. There is correspondingly little or no (induced bias) acceleration of ions to the substrate during deposition.

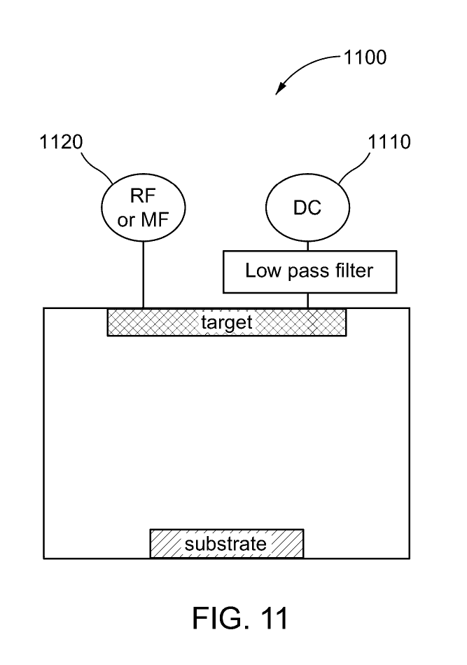

FIG. 11 is a schematic depiction of a DC RF (MF) Ripple plasma deposition system 1100, according to an embodiment, in which both an RF power supply 1120 and a DC power supply 1110 both supply power to the sputter target. Oscillating voltages, such as RF, can induce oscillating voltages on the components and electrical lines of the deposition chamber, necessitating filters to block the induced voltages from damaging other power supplies that are employed to assist in the deposition. FIG. 11 shows the incorporation of a low pass filter that blocks any RF signal from getting to the DC power supply and prevents any induced RF signal from damaging it.

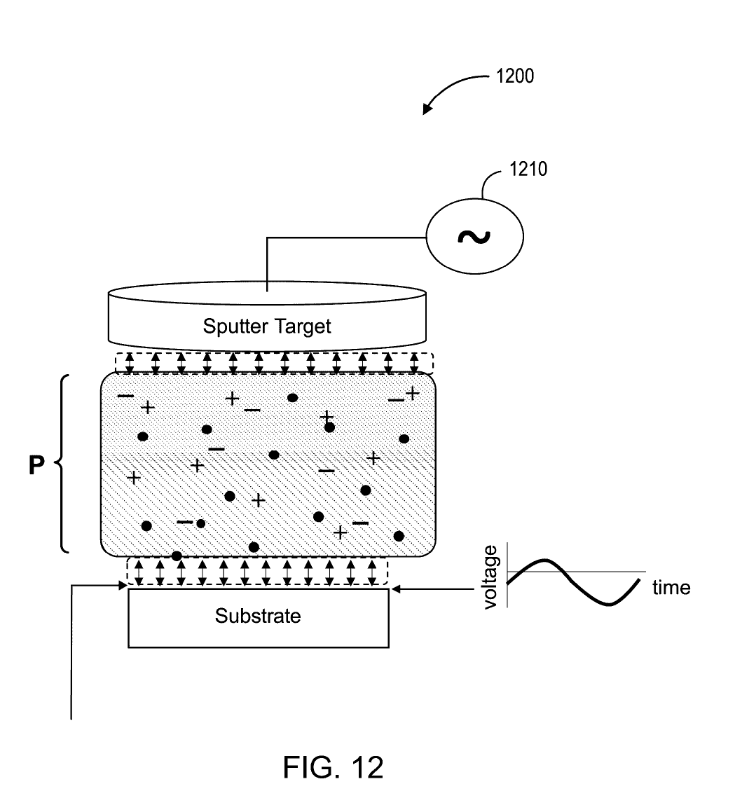

FIG. 12 is a schematic depiction of a MF plasma deposition system 1200, according to an embodiment. A MF power source supplies power to the sputter target, generating a plasma density that is higher than that of a PDC plasma, but lower than that of an RF plasma. Although the plasma extends to the substrate, as shown in FIG. 12, it is significantly weaker nearest the substrate than it is near the surface of the sputter target. A small oscillating voltage on the substrate is produced by the MF plasma, and a plasma sheath is formed at the substrate. Because the plasma is weak at the substrate surface, relatively few ions (compared to RF plasmas) are available to be accelerated towards to the substrate surface. The relative scarcity of ions combined with the small substrate voltage significantly reduces resputtering during deposition.

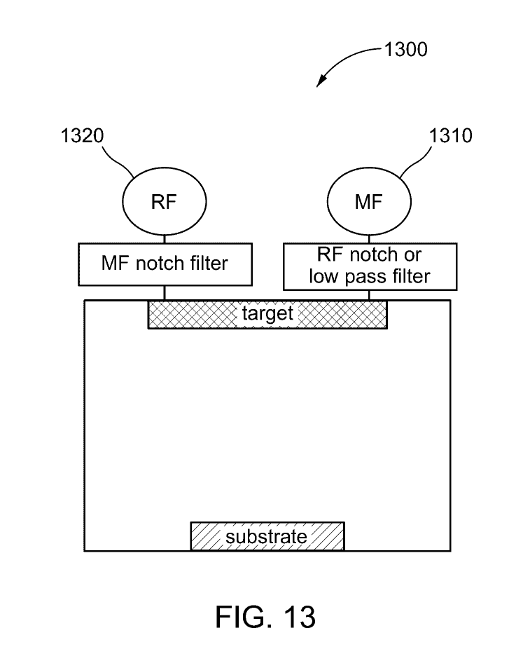

FIG. 13 is a schematic depiction of a MF RF Ripple plasma deposition system 1100, according to an embodiment, in which an RF power supply 1320 and a MF power supply 1310 both supply power to the sputter target. A MF notch filter is used to block any induced MF signal from getting to the RF power supply, and an RF notch or low pass filter is used to block any induced RF signal from getting to the MF supply, so that neither power supply is damaged by induced voltages from the other supply.

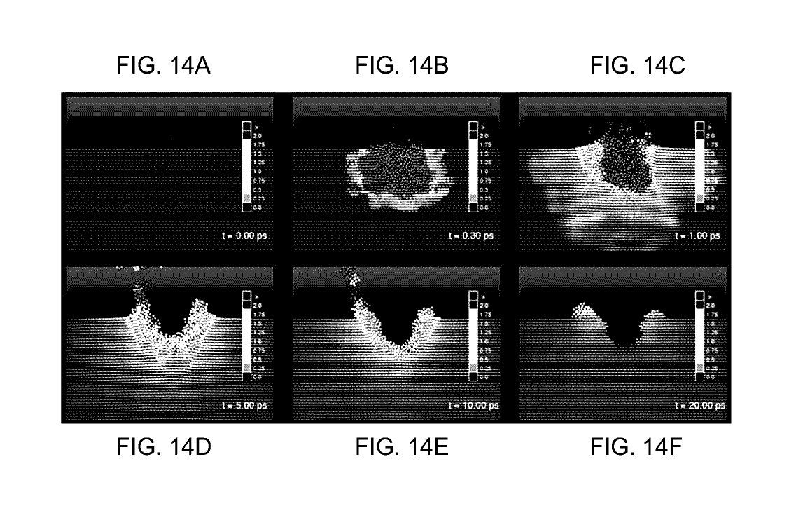

FIGS. 14A-14F show a sequence of simulated effects, over a period of 20 pico-seconds, of ion impact on a substrate. As shown, ions that are accelerated (e.g., at 100 eV or greater) into a surface, such as an existing film or a substrate, can cause ejection of large numbers of atoms. This can result in irregular topography (e.g., craters, hills) that can result in micro-voids in the film and/or modify the properties of the material. Additionally, it can result in localized changes to the composition of the surface of an existing film (e.g., previously deposited film) and/or a depositing film, since lighter atoms (e.g., lithium) are more easily (i.e., are preferentially) ejected. Localized composition changes also can modify material properties.

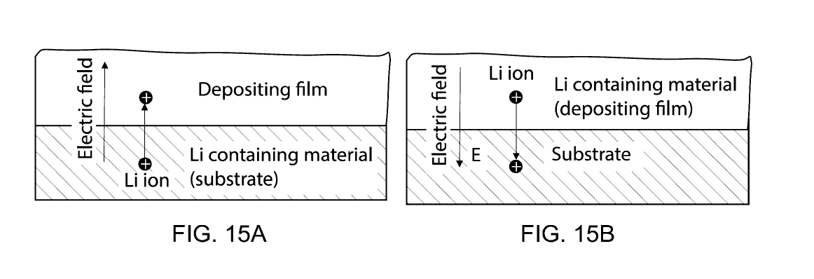

FIGS. 15A and 15B show schematic cross-sectional views illustrating substrate bias-induced ion diffusion between a previously deposited layer and a depositing layer (e.g., during RF sputtering). Induced substrate bias creates a local electric field that can drive lithium ions in the field direction. If too much lithium is driven into and/or pulled out of an ion storage layer or cathode, it can destroy that layer (e.g., LiCoO₂ can undergo an irreversible phase change into LiOₓ and CoOₓ). Excessive lithium diffusion out of the electrolyte layer can affect the electrolyte layer's ability to conduct lithium. The substrate bias created by the RF plasma creates a potential difference with respect to the substrate, which creates an electric field that drives ion diffusion between layers (positive charges are driven in the direction of the electric field).

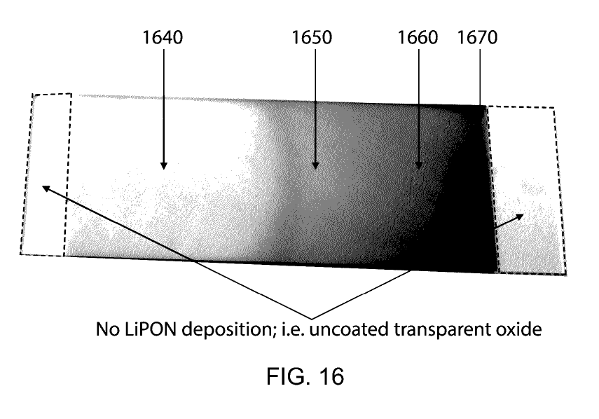

FIG. 16 shows the effects of substrate bias-induced Li ion diffusion between deposited layers. The sample shown in FIG. 16 is a transparent oxide that was coated with RF sputtered LiPON, except at the left and right edges of the sample. Inside the regions indicated by the dashed lines are the areas of uncoated oxide. When LiPON is deposited onto an initially transparent oxide, Li can readily diffuse into the oxide if the induced substrate bias reaches a sufficiently high level. Li reacting with the oxide turns the oxide dark. The lightest region 1640 in FIG. 16 represents an area that was not perturbed during the deposition (e.g., no Li ion diffusion into the oxide). The dark regions 1650, 1660, and 1670 in the right half of FIG. 16 represent areas where Li was driven into the oxide during LiPON deposition by the induced substrate bias. Darkening of the oxide increases with increasing amounts of Li being driven into the oxide by the induced substrate bias. FIG. 16 is also illustrative of the induced substrate voltage non-uniformity that often accompanies RF sputtering, which can result in non-uniform film and device properties.

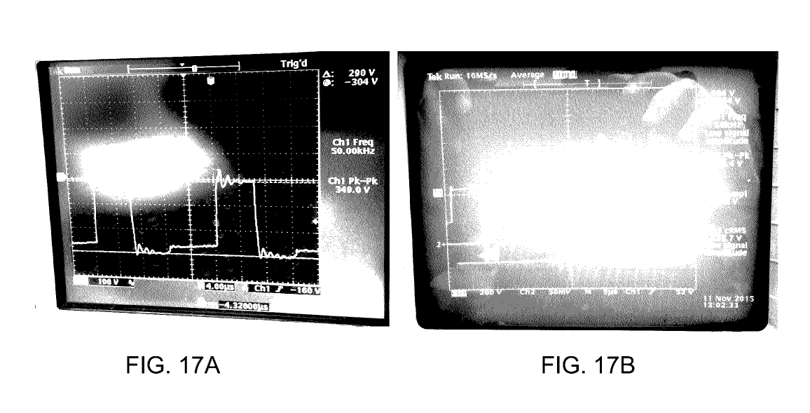

FIGS. 17A and 17B are two photographs, each showing an oscilloscope trace of voltage over time for a PDC waveform. A transition from a first (negative), “forward” voltage level to a second (positive) or zero, “reverse” voltage level, can be seen in the waveform marked “1.” Sputtering occurs during the negative portion of the pulse and neutralization of any charge on the target surface that accumulates during sputtering occurs during the reverse pulse. During the reverse pulse, ions near the target can be accelerated to the substrate. As shown in FIG. 17A, at the leading edge of the transitions to the reverse and forward voltages, however, there are oscillations at RF frequencies that can be seen as a series of small voltage spikes. In some cases, depending on the combination of power supply vendor, process conditions, and target material, the voltage spikes can reach a few hundred volts.

In the oscilloscope trace shown in FIG. 17B, no RF oscillations can be observed, but there is a large voltage spike at the onset of the forward pulse, which will accelerate any negative ions (e.g., oxygen ions) near the target to the substrate at a high energy, potentially damaging the film being deposited. In some embodiments, such effects are minimized or can be overcome through the use of a low pass filter or a protective electronic circuitry to reduce or even eliminate the magnitude of the reverse pulse. For example, advanced PDC power supplies are being developed that have the ability to mitigate the RF oscillations, reduce the magnitude of the reverse voltage, and eliminate any voltage spikes.

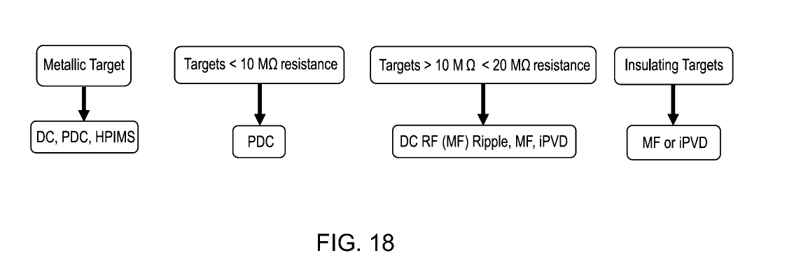

FIG. 18 shows a deposition technique selection methodology according to an embodiment. As described herein, HPIMS, DC sputtering or PDC sputtering can be used to deposit materials from metallic targets. PDC sputtering can be used to deposit materials from sputtering targets having a resistance of <about 10 MΩ (e.g., semiconductors or semi-insulators). DC RF (MF) Ripple or MF sputtering or iPVD can be used to deposit materials from sputtering targets having a resistance of >about 10 MΩ and <about 20 MΩ (e.g., semiconductors, semiinsulators). MF sputtering or iPVD can be used to deposit materials from electrically insulating sputtering targets.

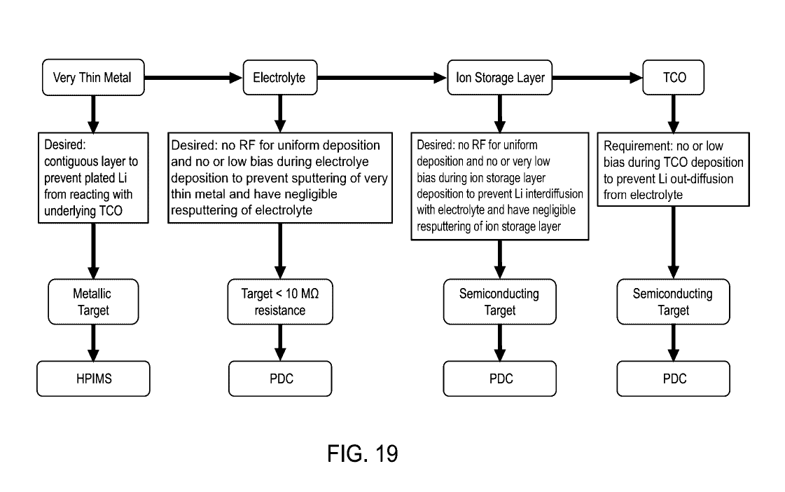

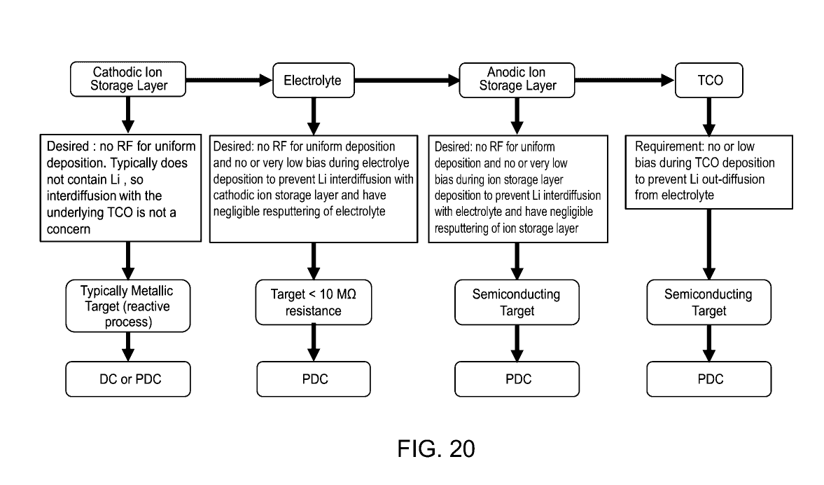

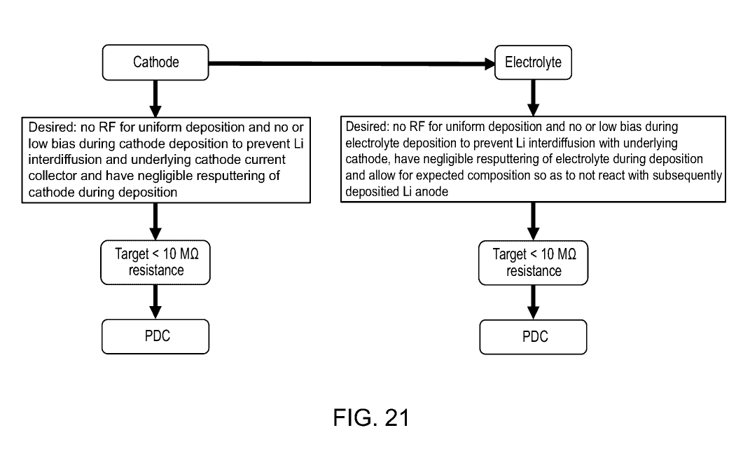

FIG. 19 shows an REC fabrication process methodology, according to an embodiment. FIG. 20 shows an AEC fabrication process methodology, according to an embodiment. FIG. 21 shows a TFB fabrication process methodology, according to an embodiment. Note that in each figure described in FIGS. 19-21, only the layers whose deposition can impact previously deposited layers are illustrated.

During a sputtering process, a plasma is generated, and one or more portions of the plasma that are in the vicinity of a surface, for example the surface of the target or the surface of the substrate, can exhibit no plasma glow. Such portions are referred to as plasma “sheaths,” and represent the transition from a plasma to a solid surface adjacent to it. Within a plasma sheath, an electric field exists between the edge of the plasma and the surface that causes charged particles to be accelerated to the surface. If the surface is initially uncharged or neutral the electric field within the sheath will accelerate charged particles from the plasma edge to that surface, thereby causing a local voltage to develop (herein referred to as an “induced bias”). If the plasma extends to the vicinity of the substrate, accelerated ions will impact the substrate, and can break bonds between substrate atoms resulting in sputtering (i.e., ejection) of atoms from the substrate (also referred to herein as “resputtering”).

In RF sputtering, a medium-density capacitive plasma, created by two electrodes—the target and substrate—at different potentials (such configuration being analogous to an actual capacitor), typically extends throughout the deposition chamber and reaches the substrate. The induced bias, or induced substrate voltage, that develops within capacitive plasmas can be very large, e.g. hundreds of volts, and can produce undesired effects such as reduced deposition rate, composition gradients and the creation of layer defects such as pinholes. When RF sputtering is used to deposit a Li-containing layer, or to deposit a layer onto a Li-containing material, the induced substrate bias can cause diffusion of Li into and/or out of one or more pre-existing films, with the potential result of: (1) changing the composition and/or crystal structure of the film(s), (2) degrading the device performance of the eventual device that contains the film(s), and/or (3) resulting in an altogether non-functional device. An example of such problematic effects, relating to TFBs, is the diffusion of Li into and/or out of a lithium cobalt oxide (LiCoO₂) cathode during LiPON deposition, which can cause over-discharging and/or overcharging of the LiCoO₂, both of which can result in an irreversible reduction of the LiCoO₂ into lithium and cobalt oxides. Resputtering of the depositing layer by the induced substrate bias can also alter the composition of the depositing layer as it is being formed, for example since “light” elements (i.e., having a low atomic mass) such as Li and O may be preferentially removed from the film, altering its composition. This altered composition can lead to undesired reactions with subsequently deposited material, as the resulting film may become metastable due to its altered composition. For example, during deposition of an anodic storage layer onto LiPON for EC devices, an interfacial reaction can occur that creates a high resistance to Li ion transport across the interface between the anodic storage layer and the LiPON, resulting in a slower device switching speed. Another issue that occurs with sputtering of the depositing layer (i.e., “resputtering”) is a mass ejection event, in which many substrate atoms are removed from the film, altering local film composition and/or resulting in uneven surface topography such as craters and hills. The presence of hills in the depositing film can cause subsequent shadowing of the craters from the depositing material, resulting in micro-voids, some of which may grow to a greater extent during the remainder of the deposition process. The aforementioned detrimental effects of RF are widely unappreciated when RF sputtering techniques are applied to Li-ion device fabrication. Furthermore, given the difficulty and cost of scaling RF sputtering to larger chamber dimensions to reduce manufacturing costs, the elimination of RF sputtering in Li-ion device manufacturing, and replacing it with a process that either eliminates or significantly reduces the induced substrate bias, is highly desirable.

As described herein, process alternatives to traditional RF sputtering are presented. The present disclosure relates to methods for the fabrication of thin film lithium ion devices, and more specifically, to methods that do not use standard RF sputtering, but instead employ a combination of several techniques (e.g., DC, PDC, HPIMS (high power impulse magnetron sputtering), iPVD, DC RF ripple, DC MF ripple, MF (medium frequency) and mixed frequency MF RF ripple sputtering) to optimize resulting film and device properties. Methods described herein are high throughput, scalable manufacturing techniques that are compatible with current high volume window manufacturing methods, and provide advantages over current TFB and EC manufacturing methodology (e.g., preserving the compositional integrity of all layers, preventing Li diffusion between layers, etc.). Eliminating RF sputtering from the fabrication of Li-ion devices can help to preserve the integrity of the unit layers within the devices and/or provide well defined interfaces between such layers. Process alternatives to RF sputtering can include one or more deposition techniques that: (1) reduce the oscillation frequency of the source (induced voltage scales with source frequency); (2) use a high density inductive plasma resulting in a very low substrate bias; (3) significantly reducing the RF power applied to a target; and/or (4) eliminating sinusoidal oscillating sources to effectively decouple the substrate from the plasma and eliminating (or render negligible) an induced substrate bias. The latter three methods can involve the use of targets that have at least some degree of DC conductivity (e.g., such that a standard multimeter put on the resistance measurement setting will produce a finite resistance value). Furthermore, as described herein, the selection of one or more deposition techniques, for example for the deposition of sequential layers in a multilayer thin film device, can differ from layer to layer, and can be based on one or more of the following (by way of example only): (1) the presence of fast ion diffusers (e.g., Li) and light elements (which are more prone to resputtering) in the deposited film in question; (2) the conductivity (e.g., conductive, semiconductive, or insulating) of the substrate onto which the layer will be deposited; (3) the composition of one or more existing films that have already been deposited onto a substrate and upon which the layer will be deposited, particularly if said layer contains fast ion diffusers such as Li; (4) the function that the layer will serve in the completed device, such as the need for a thin, contiguous diffusion barrier, etc.

In some embodiments, reduced frequency plasma processing, for example medium frequency (MF) plasma processing, employs sources whose potential oscillates at frequencies between about 40 kHz and about 500 kHz, as compared with standard RF processing which takes place between about 1 and 300 MHz (most often at 13.56 MHz). As such, MF sputtering reduces the source frequency by at least a factor of 26 compared to typical RF processes, which will reduce the magnitude of induced biases in the deposition chamber.

In some embodiments, a dense inductive plasma can be created using ionized physical vapor deposition (iPVD). During iPVD, RF power is applied to the deposition chamber (not to the target) using a metal coil, for example in combination with direct current (DC) or pulsed direct current (PDC) sputtering. In PDC sputtering, the target voltage polarity is switched between positive and negative at a regular interval, for example to minimize or prevent charge build up and subsequent arcing as a result of the built up charge, on non-metallic targets or during reactive depositions in which a thin nitride, oxide, or oxynitride layer may be present on the sputtering target surface. The use of inductive plasmas can reduce the induced substrate bias to less than about 10 volts, as opposed to the lower-density capacitive plasmas of standard RF processing whose induced substrate bias can reach hundreds of volts.

In some embodiments, when the sputtering target has some limited DC conductivity (e.g., a multimeter resistance of less than about 20 Me but greater than about 10 Me), applying both a low power RF or MF signal and DC/PDC power to the sputtering target (such process herein referred to as “DC RF ripple” or “DC MF ripple”) can lower the induced substrate bias as compared with traditional RF sputtering, for example due to the significant reduction of RF power or reduction in frequency when MF is used and the accompanying reduction of plasma density at the substrate. A mixed frequency sputter source with MF providing the majority of the power along with a low power RF signal can also be employed in the embodiment where the target has limited or no DC conductivity.

In some embodiments, oscillating sources can be completely eliminated, thereby allowing the use of PDC sputtering (e.g., if the DC resistance of the target is less than 10 Me). A highly conductive (e.g., metallic) sputtering target can allow use of DC sputtering. DC plasmas are confined to the vicinity of the target and do not extend to the substrate (when the sputter cathode magnetics are properly designed to prevent normal magnetic fields from reaching the substrate), thus effectively isolating the substrate from the plasma ions, and reducing or eliminating induced bias from forming on the substrate. It should be noted that PDC signals can exhibit voltage spikes and high power RF oscillations when the polarity of the voltage is switched, temporarily inducing a substrate bias, and as a consequence, high energy ions can be accelerated from the target to the substrate immediately after switching (e.g., when the target voltage can instantaneously spike), for example if the ions have the same polarity as the target voltage. As such, care must be taken to select a PDC supply which has the capability to eliminate or limit RF rippling, control the magnitude of the reverse voltage, and/or eliminate voltage spiking.

In some embodiments, layers are fabricated in a way that takes into account the high diffusivity of Li. For example, the metal layer used as a diffusion barrier in RECs to prevent diffusion of Li into the TCO (which can severely degrade the TCOs optical transmission and conductivity) can be deposited to a very low thickness (i.e., a very thin layer), for example from about 2 nm to about 10 nm, from about 2 nm to about 4 nm, from about 2 nm to about 6 nm, from about 2 nm to about 8 nm, from about 4 nm to about 6 nm, from about 4 nm to about 8 nm, from about 4 nm to about 10 nm, from about 6 nm to about 8 nm, from about 6 nm to about 10 nm, or from about 8 nm to about 10 nm, or in some embodiments, less than about 4 nm, to allow for the highest possible optical transmission, while also being physically continuous so that it functions effectively as a diffusion barrier. Those two objectives may not be simultaneously achieved using standard DC sputtering or PE. In some embodiments, high power impulse magnetron sputtering (HPIMS) and/or ionized physical vapor deposition (iPVD) are used to produce dense plasmas and result in nearly two orders of magnitude higher ionization fraction of the depositing metal than standard DC sputtering, which can be then be accelerated at low voltage at normal and near normal incidence to the substrate, thus achieving continuous films at very low thicknesses. iPVD can also be used to deposit the electrolyte layers of Li ion devices.

In some embodiments, deposition techniques of the present disclosure are performed in a deposition chamber (e.g., a vacuum chamber), for example having a base pressure of from about 1×10⁻⁸ Torr to about 5×10⁻⁶ Torr, from about 1×10⁻⁸ Torr to about 5×10⁻⁸ Torr, from about 5×10⁻⁸ Torr to about 1×10⁻⁷ Torr, from about 1×10⁻⁸ Torr to about 1×10⁻⁷ Torr, from about 1×10⁻⁷ Torr to about 5×10⁻⁷ Torr, from about 1×10⁻⁷ Torr to about 5×10⁻⁶ Torr, or from about 1×10⁻⁶ Torr to about 5×10⁻⁶ Torr.

In some embodiments, the deposition of a LiPON layer can be performed at an operating pressure of about 5 milliTorr (mT) to about 30 mT. In some embodiments, the deposition of a LiPON layer (e.g., having a layer thickness of about 0.5 μm to 1.5 μm, or of about 0.5 μm to about 0.7 μm) can be performed using PDC sputtering (e.g., for an electrically conductive or semiconducting sputtering target), MF sputtering (e.g., for an electrically insulating sputtering target), or DC RF ripple sputtering or DC MF ripple sputtering (e.g., for an semiconducting or semi-insulating sputtering target), at an operating pressure of about 5 mT to about 30 mT. Said another way, in some embodiments, wherein the depositing of the electrolyte layer can be performed via at least one of MF sputtering, DC MF ripple sputtering, DC RF ripple sputtering, and non-RF sputtering of the electrolyte where the target is not electrically conductive enough to use PDC sputtering. In some embodiments, the deposition of a LiPON layer can be performed using iPVD sputtering (e.g., using an electrically conductive sputtering target, semiconducting, semi-insulating, or an electrically insulating sputtering target), at an operating pressure of greater than or equal to about 15 mT.

In some embodiments, the deposition of an ion storage layer (either anodic ion storage layer or cathodic ion storage layer) can be performed at an operating pressure of about 20 mT to about 50 mT, 25 mT to about 50 mT, 30 mT to about 50 mT, 35 mT to about 50 mT, 20 mT to about 45 mT, 25 mT to about 45 mT, 30 mT to about 45 mT, 35 mT to about 45 mT, 20 mT to about 40 mT, 25 mT to about 40 mT, 30 mT to about 40 mT, 35 mT to about 40 mT, 20 mT to about 35 mT, 25 mT to about 35 mT, or 30 mT to about 35 mT. The deposition of the ion storage layer can be performed using MF sputtering (e.g., for an electrically insulating sputtering target) or using PDC sputtering (e.g., for an electrically conductive or semiconducting sputtering target), or using DC RF ripple sputtering or DC MF ripple sputtering (e.g., for a semiconducting or semi-insulating sputtering target).

In some embodiments, the ion storage layer can be either anodic ion storage layer or cathodic ion storage layer, and can have a thickness of about 100 nm to about 400 nm, about 100 nm to about 350 nm, about 100 nm to about 300 nm, about 100 nm to about 250 nm, about 100 nm to about 200 nm, about 150 nm to about 400 nm, about 150 nm to about 350 nm, about 150 nm to about 300 nm, about 150 nm to about 250 nm, about 150 nm to about 200 nm, about 200 nm to about 400 nm, about 200 nm to about 350 nm, about 200 nm to about 300 nm, about 200 nm to about 250 nm, about 250 nm to about 400 nm, about 250 nm to about 350 nm, or about 250 nm to about 300 nm. In some embodiments, the ion storage layer can be either anodic ion storage layer or cathodic ion storage layer, and can have a thickness of about 100 nm, about 150 nm, about 200 nm, about 250 nm, about 300 nm, about 350 nm or about 400 nm.

In some embodiments, the deposition of a thin metal layer such as a “barrier layer” (e.g., having a layer thickness of about 2 nm to about 10 nm, about 2 nm to about 4 nm, about 2 nm to about 6 nm, about 2 nm to about 8 nm, about 4 nm to about 6 nm, about 4 nm to about 8 nm, about 4 nm to about 10 nm, about 6 nm to about 8 nm, about 6 nm to about 10 nm, or about 8 nm to about 10 nm, or in some embodiments, of less than about 4 nm) can be performed using HPIMS at an operating pressure of about 0.5 mT to about 5 mT, or of less than about 2 mT. In some embodiments, the deposition of a thin metal layer, such as a “barrier layer” (e.g., having a layer thickness of about 2 nm to about 10 nm, about 2 nm to about 4 nm, about 2 nm to about 6 nm, about 2 nm to about 8 nm, about 4 nm to about 6 nm, about 4 nm to about 8 nm, about 4 nm to about 10 nm, about 6 nm to about 8 nm, about 6 nm to about 10 nm, or about 8 nm to about 10 nm, or in some embodiments, of less than about 4 nm) can be performed using iPVD at an operating pressure of about 30 mT to about 75 mT, or of about 60 mT.

In some embodiments, a metallic anode is a lithium metal and has a thickness of about 3 μm to about 10 μm, or about 3 μm to about 10 μm. The lithium metal can be deposited after the electrolyte by physical evaporation or pulsed direct current sputtering. The anode current collector, which is deposited after lithium deposition can include any conducting material that is not-reactive with lithium and has very limited or no solid solubility for lithium. Examples of these current collector materials include nickel and tantalum.

For embodiments employing PDC sputtering (e.g., using an electrically conductive sputtering target), the deposition power source can have at least one of: (1) a frequency range of about 5 kHz to about 350 kHz, or of about 40 kHz to about 150 kHz; (2) a reverse time of about 0.5 μs to about 10 μs, or of about 6 μs; and/or (3) a target power density of about 10 W/in² to about 20 W/in², about 10 W/in² to about 25 W/in², about 10 W/in² to about 30 W/in², about 10 W/in² to about 40 W/in², about 15 W/in² to about 25 W/in², about 15 W/in² to about 30 W/in², about 15 W/in² to about 40 W/in², or of greater than about 25 W/in².

For embodiments employing DC RF Ripple sputtering (e.g., using semiconducting or semi-insulating sputtering target), the deposition power source can have at least one of: (1) an RF ripple frequency of about 2 MHz, or of about 13.56 MHz; (2) a target DC power density of about 10 W/in² to about 20 W/in², about 10 W/in² to about 25 W/in², about 10 W/in² to about 30 W/in², about 10 W/in² to about 40 W/in², about 15 W/in² to about 25 W/in², about 15 W/in² to about 30 W/in², about 15 W/in² to 40 W/in², or of greater than about 25 W/in²; and/or (3) a target RF ripple power density of less than about 25% of the DC power density, or of less than about 10% of the DC power density.

For embodiments employing DC MF Ripple sputtering (e.g., using an electrically conductive sputtering target), the deposition power source can have at least one of: (1) a MF ripple frequency of about 40 kHz to about 500 kHz, or of about 300 kHz to about 500 kHz; (2) a target DC power density of about 10 W/in² to about 20 W/in², about 10 W/in² to about 25 W/in², about 10 W/in² to about 30 W/in², about 10 W/in² to about 40 W/in², about 15 W/in² to about 25 W/in², about 15 W/in² to about 30 W/in², about 15 W/in² to 40 W/in², or of greater than about 25 W/in²; and/or (3) a target RF ripple power density of less than about 25% of the DC power density, or of less than about 10% of the DC power density.

For embodiments employing MF sputtering (e.g., using an electrically insulating sputtering target), the deposition power source can have at least one of: (1) a frequency range of about 40 kHz to about 500 kHz, or of about 300 kHz to about 500 kHz; (2) a target power density of about 10 W/in² to about 20 W/in², about 10 W/in² to about 25 W/in², about 10 W/in² to about 30 W/in², about 10 W/in² to about 40 W/in², about 15 W/in² to about 25 W/in², about 15 W/in² to about 30 W/in², about 15 W/in² to about 40 W/in², or of greater than about 25 W/in².

For embodiments employing iPVD sputtering (e.g., using an electrically insulating, semi-insulating, semiconducting, or an electrically conducting sputtering target), the base pressure can be about 1×10⁻⁸ Torr to about 5×10⁻⁷ Torr, or about 1×10⁻⁷ Torr to about 5×10⁻⁷ Torr. (Without wishing to be bound by theory, the higher base pressure for iPVD can be necessitated by the cracking of residual water in the chamber (by high density plasmas) into H₂ and O₂. The H₂ residence time for turbo and cryo pumps is very high, resulting in H₂ becoming incorporated into films with unknown results). The deposition power source for iPVD sputtering can have at least one of: (1) a target power density of about 10 W/in² to about 20 W/in², about 10 W/in² to about 25 W/in², about 10 W/in² to about 30 W/in², about 10 W/in² to about 40 W/in², about 15 W/in² to about 25 W/in², about 15 W/in² to about 30 W/in², about 15 W/in² to 40 W/in², or of greater than about 25 W/in² for ion storage and LiPON layers; (2) a target power density of up to about 200 W/in² for thin metal layers; (3) an RF coil frequency of about 13.56 MHz; and (4) an RF coil power density of about 2 W/in³ to about 7 W/in³.

For embodiments employing HPIMS sputtering, the base pressure can be about 1×10⁻⁸ Torr to about 5×10⁻⁶ Torr, or from about 1×10⁻⁷ to about 5×10⁻⁶ Torr and the deposition power source can have peak output power up to about 8 MW, peak output voltage up to 2 kV, peak output current up to 4 A, average power up to 20 kW, with pulse frequency up to 500 Hz and pulse duration up to 200 μs.

Embodiments described herein relate generally to methods and systems for the fabrication of any type of thin film lithium-ion device. Any individual method or combination of methods described herein can be used in the fabrication of one or more layers of a given device.

As used herein, the terms “about” and “approximately” generally mean plus or minus 10% of the value stated, for example about 250 μm would include 225 μm to 275 μm, and about 1,000 μm would include 900 μm to 1,100 μm.

While various embodiments of the system, methods and devices have been described above, it should be understood that they have been presented by way of example only, and not limitation. The embodiments have been particularly shown and described, but it will be understood that various changes in form and details may be made.

1. A method of making a reflective electrochromic device, the method comprising:
depositing, via pulsed direct current sputtering, a first transparent conducting oxide material on a substrate;
depositing an electrolyte layer;
depositing, via pulsed direct current sputtering, an ion storage layer; and
depositing, via pulsed direct current sputtering, a second transparent conducting oxide material.

2. The method of claim 1, wherein the first transparent conducting oxide material includes at least one of indium tin oxide, fluorine doped tin oxide, and aluminum doped zinc oxide.

3.-9. (canceled)

10. The method of claim 1, wherein the electrolyte layer is deposited via at least one of pulsed direct current sputtering or reactive pulsed direct current sputtering of a non-insulating target.

11.-16. (canceled)

17. The method of claim 1, wherein the electrolyte layer is deposited via at least one of MF sputtering, DC MF ripple sputtering, MF RF ripple, DC RF ripple sputtering, and non-RF sputtering.

18. The method of claim 17, wherein the electrolyte layer is deposited in a reactive environment and the environment includes at least one of oxygen and nitrogen.

19. The method of claim 1, wherein the ion storage layer includes at least lithium nickel oxide.

20. (canceled)

21. (canceled)

22. The method of claim 1, wherein the ion storage layer is deposited via pulsed direct current sputtering or reactive pulsed direct current sputtering of a non-insulating target.

23. The method of claim 22, wherein the pulsed direct current sputtering or reactive pulsed direct current sputtering is performed with an operating pressure of about 15 mT to about 30 mT.

24.-27. (canceled)

28. The method of claim 1, wherein the electrolyte layer is deposited on the ion storage layer.

29.-33. (canceled)

34. The method of claim 1, wherein the second transparent conducting oxide material is deposited on at least one of the electrolyte layer and the ion storage layer.

35. The method of claim 1, wherein all layers are deposited without exposure to atmospheric pressure.

36. (canceled)

37. A method of making an absorptive electrochromic device, the method comprising:
depositing, via pulsed direct current sputtering, a first transparent conducting oxide material on a substrate;
depositing, via pulsed direct current sputtering, a first ion storage layer;
depositing an electrolyte layer;
depositing, via pulsed direct current sputtering, and a second ion storage layer; and
depositing, via pulsed direct current sputtering, a second transparent conducting oxide material.

38.-40. (canceled)

41. The method of claim 37, wherein the electrolyte layer is deposited via reactive pulsed direct current sputtering.

42. The method of claim 37, wherein the electrolyte layer is deposited via ionized physical vapor deposition or reactive ionized physical vapor deposition.

43. The method of claim 37, wherein the electrolyte layer is deposited via at least one of MF sputtering, DC MF ripple sputtering, MF RF ripple, DC RF ripple sputtering, and non-RF sputtering.

44.-47. (canceled)

48. The method of claim 47, wherein the non-insulating target has a resistance of about 5 kΩ to 10 MΩ.

49.-72. (canceled)

73. A method of making a lithium ion battery, the method comprising:
depositing, via direct current sputtering, a cathode current collector;
depositing, a cathode layer;
depositing, an electrolyte layer;
depositing, a metallic anode; and
depositing via direct current sputtering, an anode current collector.

74.-89. (canceled)

90. The method of claim 73, wherein the electrolyte layer is deposited via at least one of pulsed direct current sputtering or reactive pulsed direct current sputtering of a non-insulating target.

91. The method of claim 73, wherein the electrolyte layer is deposited via at least one of MF sputtering, DC MF ripple sputtering, MF RF ripple, DC RF ripple sputtering, and non-RF sputtering.

92. (canceled)

93. The method of claim 73, wherein the metallic anode has a thickness of about 3 μm to about 10 μm.

94.-106. (canceled)
